(19) United States
(12) Patent Application Publication
(10) Pub. No.: US 2014/0069324 A1
(43) Pub. Date: Mar. 13, 2014

(54) CRUCIBLE AND METHOD FOR PRODUCING A SILICON BLOCK

(71) Applicant: Bjoern SEIPEL, Portland, OR (US)

(72) Inventor: Bjoern SEIPEL, Portland, OR (US)

(21) Appl. No.: 13/606,548

(22) Filed: Sep. 7, 2012

(51) Int. Cl. C30B 15/10; C30B 15/04; C30B 11/04; C30B 11/00

(52) U.S. Cl. CPC C30B 15/10; C30B 11/002; C30B 15/04; C30B 11/04
USPC 117/19; 117/206; 117/208; 117/81

(57) ABSTRACT

A crucible for producing a silicon block comprises a crucible wall surrounding an interior and an opening for filling silicon melt into the interior, wherein the crucible wall comprises at least one doping means for providing dopant for the silicon melt.

### FIELD OF THE INVENTION

The invention relates to a crucible and a method for producing a silicon block.

### BACKGROUND OF THE INVENTION

The production of large-volume silicon blocks is a key step in the production process of silicon solar cells. It is further known to use dopants in order to provide integrated functionality of the produced silicon block.

For that purpose at least one dopant is introduced into a silicon melt, whereas the dopant is gaseous or solid. According to the design of the heat zone in the crucible and in the silicon melt, doping is limited. In particular it is not possible to provide in situ-doping. It is disadvantageous that replenishing of the concentration of the dopant is limited, too.

### SUMMARY OF THE INVENTION

It is therefore an object of the invention to improve a crucible and a method for producing a silicon block.

These objects are achieved by a crucible for producing a silicon block, the crucible comprising a crucible wall surrounding an interior, and an opening for filling silicon into the interior, wherein the crucible wall comprises at least one doping means for providing a dopant for the silicon within the crucible.

These objects are further achieved by a method for producing a silicon block, the method comprising the following steps of providing a crucible, comprising a crucible wall surrounding an interior, and an opening for filling silicon into the interior, wherein the crucible wall comprises at least one doping means for providing a dopant for the silicon in the crucible, providing a silicon melt in the interior of the crucible, starting crystallization of a silicon crystal, and doping the silicon crystal with the at least one doping means, wherein doping is based on at least one of a diffusion process and a dissolution process of the at least one doping means.

The gist of the invention is to provide a dopant as being part of the crucible wall. Doping is done by at least one of a diffusion process and a dissolution process of the at least one doping means into the silicon melt in the crucible. Thus, the doping means does not form seeds which would initiate the crystallization of the silicon melt.

It has been found that based on the at least one of the diffusion process and the dissolution process the dopant concentration in the silicon melt is replenished during a growth of a silicon crystal. Since it is not necessary to introduce the gaseous or solid dopant directly into the melt, replenishing of the dopant in the melt is simplified. In particular, the inventive method and the inventive crucible enable doping of the silicon melt independent of a heat zone in the crucible and in the melt. Thus, a method for producing a silicon block is stable and robust. The crucible itself is used as source for the at least one doping means. The inventive crucible and the inventive method can be used for both, the Czochralski-method and heat exchange methods, in particular a vertical gradient freeze method, for producing a silicon block. In particular, the inventive crucible and the inventive method enable the production of a silicon block, whereas a block is understood as being either a Czechralski-monocrystal, a multicrystal-silicon block or a monocrystal-silicon block.

According to an advantageous embodiment of the invention, the at least one doping means is provided in the crucible wall with a pre-defined profile such that the doping of the silicon block to be produced has pre-defined characteristics. As characteristic, a profile of the dopant in the ingot, a distribution of the dopant in the ingot, in particular distribution along a longitudinal axis of the ingot and/or a distribution of the dopant across a cross sectional area perpendicular to the longitudinal axis of the ingot and/or a homogeneity of the dopant in the ingot can be understood. The pre-defined profile of the doping means can be characterized by the spatial distribution of at least one of the following parameters: amount of the doping means, concentration of the doping means, composition of the at least one doping means. The doping means can in particular be provided with a constant profile throughout a given range of the inner crucible wall. It can also be provided with a linearly changing profile. The profile can vary with respect to a direction parallel to the crucible wall and/or perpendicular thereto.

According to an advantageous embodiment of the invention, the at least one doping means is at least one of an oxide, a nitride, a phosphate and a doped silicon powder. In particular, the at least one doping means is at least one of Ga₂O₃, B₂O₃, GeO, BN, Si₃N₄, Si₃(PO₄)₄ and SiAlON. It has been found that these materials provide enhanced doping results. However, other doping materials can be used according to the intended use of the produced silicon block. It is also possible to provide a combination of said materials.

According to an advantageous embodiment, the doping means is provided as grains. The grain size of the at least one doping means is smaller than 50 μm, in particular smaller than 25 μm and in particular smaller than 10 μm. Thus, the dissolution behavior of such grains is enhanced. In particular, such grains are dissolved faster.

In an advantageous embodiment the at least one doping means is at least one of crystalline and amorphous. In particular, an amorphous doping means enables fast dissolution in the silicon melt. However, crystalline doping means are cheap. The use of the kind of the at least one doping means, i. e. crystalline or amorphous, depends on the production method for producing a silicon block.

In an advantageous embodiment a concentration of the at least one doping means in the crucible wall is in the range of 1 to 500 ppm. It has been found that an ingot produced with such crucible comprises advantageous features for the use for photovoltaic purposes. Depending on an intended use of the produced silicon block, the concentration of the at least one doping means can be smaller that 1 ppm or greater than 500 ppm.

According to an advantageous embodiment, at least one of the concentration and amount of the at least one doping means is variable along a direction parallel and/or along a direction perpendicular to an inner surface of the crucible wall. In other words, the doping means can have a predefined profile along the crucible wall. Thus, it is possible to provide a controlled diffusion and/or dissolution process of the at least one doping means into the silicon melt. For instance it is possible to provide a higher concentration of the at least one doping means in a vicinity of an upper opening of the crucible. Such concentration is at least 300 ppm, in particular at least 500 ppm and in particular at least 1000 ppm. Once the filling level comes below a certain height, no further doping of the silicon melt is provided. In particular, it is possible to control the amount of doping by the height of the filling level of the silicon melt in the crucible. For instance it is possible to modify the height of the filling level by refilling silicon melt into the crucible. In particular, such method is advantages for either recharging silicon melt or a continuous feed of silicon melt into the crucible. Alternatively it is possible to provide a certain amount of the at least one doping means in the bottom of the crucible. A resulting doping of the silicon melt is defined by a dissolution rate of the crucible, wherein the dissolution rate is in the range of 3 μm/h to 10 μm/h. Both methods, higher doping of the crucible wall in the vicinity of the crucible opening and doping of the bottom of the crucible, are provided for a one-time doping. It is further possible to provide several layers on an inner surface of the crucible wall. The layers may vary in a layer thickness in a direction perpendicular to the inner surface. Further, the layers may comprise different doping means. These different layers can be arranged neighboring to each other to build one single layer which is arranged on the inner surface of the crucible wall. That means that the so-built inner layer comprises locally different properties concerning layer thickness and concentration of the at least one doping means. The so-built inner layer is a common layer. The common layer is of patchwork-design having several different patches. For instance it is possible to provide the different thicknesses of the layers based on growth rates of the crystals on the one hand and a length of the crystals on the other hand. If it is intended to use undoped silicon melt for the production of a silicon block, it is possible to provide a layer comprising at least one doping means, wherein the concentration of the at least one doping means increases in a direction from the crucible opening to the crucible bottom. As the at least one doping means is built up by segregation, a smaller amount of new doping is necessary. For this purpose the concentration of the at least one doping means is in the range of 1 ppm to 1000 ppm, in particular in a range between 50 ppm to 700 ppm and in particular in a range between 100 ppm to 500 ppm.

If it is intended to use a crucible several times, in particular for several re-fillings of silicon melt, a uniform layer is to be provided. The uniform layer has up to 1%, in particular up to 1000 ppm, of the at least one doping means. It is possible to produce several silicon blocks out of one crucible.

According to an advantageous embodiment the profile of the doping means, in particular at least one of the concentration, distribution and amount of the at least one doping means, is adjusted, such that the crystallized silicon block, which is also called an ingot, has a predefined doping profile. By that it is meant, that the doping of the ingot, i. e. the concentration of the dopant in the ingot, has a predefined distribution or gradient. In particular, it is possible to ensure, that the crystallized ingots have a homogeneous doping. More generally, the doping of the ingot varies by at most 10% from a mean value.

According to an advantageous embodiment, the at least one doping means is provided as a doping layer of the crucible wall, the doping layer providing at least partially an inner surface of the crucible wall. The doping means can partly or fully cover the crucible wall. Thus, it is possible to directly influence the doping process, since the size of the part of the inner surface which is provided as the doping layer influences the amount of dopant which is to be dissolved in the silicon melt. Further, it is possible to modify the arrangement of one or more doping layers on the inner surface.

For instance it is possible to provide the doping layer at a upper region of the crucible wall, i. e. next to the crucible opening However, it is also possible to provide a layer of any desired shape in order to enhance the doping process. In particular, it is possible to provide a doping layer as a pattern, e. g. a grid-structure or a plurality of layer spots that are arranged on the inner surface statistically or regularly.

According to an advantageous embodiment, the doping layer fully covers the inner surface of the crucible wall. Thus, doping of the silicon melt is guaranteed independent of a current filing level of the silicon melt in the crucible.

According to an advantageous embodiment of the invention, the thickness of the doping layer is variable. In particular, the thickness of the doping layer is thin in a region next to the opening of the crucible. In particular, the thickness of the doping layer is thick in a region next to the bottom of the crucible. In particular, it is possible to provide a linear ramp between a thin doping layer at the crucible opening and a thick doping layer at the crucible bottom. However, any intersection of different layer thicknesses is possible. In particular, the layer thickness can depend on a production method used for producing a silicon block, i. e. single pull-method or continuous feed-method. For instance a dissolution rate of silicon dioxide SiO₂ is in a range of 3 μm/h to 10 μm/h. Based on a dissolution rate of 10 μm/h an amount of 10¹⁶ 1/cm³ boron-atoms is to be provided in the silicon melt in order to have an intended overall concentration of 10¹⁶ 1/cm³ boron-atoms in the whole silicon block. Assuming the volume of the silicon melt is 80000 cm³, 8*10²⁰ boron-atoms are necessary for doping the silicon melt. The inner surface of the crucible wall which is bewetted of the silicon melt is for instance 15000 cm². Thus, the necessary amount of boron-concentration in the crucible is 5*10¹⁹ 1/cm³. It is therefore necessary to dissolve 16 cm³ of the crucible in order to get the amount of 8*10²⁰ boron-atoms into the silicon melt. For doping the doping layer B₂O₃ is used. The molar mass of B₂O₃ is 69.6 g/mol. The molar mass of silicon dioxide is 60.1 g/mol. The density of the crucible material is 1.9 g/cm³. Thus, 0.26 mass-% B₂O₃ is necessary in the silicon dioxide of the doping layer. Within the time interval between melting and solidifying, which is for instance 1.06 h, a layer having a thickness of 10.6 μm of the crucible is dissolved. The multiplication of 10.6 μm layer thickness and 15000 cm² doped surface of the crucible wall results in 16 cm³ of necessary amount of the crucible to be dissolved. Thus, the concentration of boron-atoms in the silicon melt is 10¹⁶ 1/cm³.

During a real process it is possible to allow the silicon melt to stand for several hours for homogenization and for exact adjustment of a temperature being necessary for starting the crystallization process. It is also possible to provide a double-layer on the inner surface of the crucible wall. A first layer is provided on the crucible wall. The first layer is a doping layer. A second layer is provided on the first layer. In particular, the second layer is not directly provided on the crucible wall. The second layer contains pure silicon dioxide. The second layer may have a layer thickness of 20 μm. The layer thickness of the first layer is 10.6 μm. The production method starts with melting the silicon. As longer the melting takes place, the more volume of the silicon melt gets into contact with the inner surface of the crucible wall. During this time the inner most second layer containing pure silicon dioxide dissolves slowly and locally. Once the silicon is molt completely a waiting period of preferably 2 h is necessary. During this waiting period the second layer is dissolved completely. Further, the first layer is locally dissolved, too. Waiting a further period of preferably 1.06 h, the first layer is dissolved completely, too. After that the crucible wall itself is dissolved, whereas the crucible wall itself does not comprise any doping means.

According to an advantageous embodiment of the invention the at least one doping means is provided as a doping tablet. The doping tablet can be fixed in a provided recess within the crucible wall. In particular, it is possible to provide the recess with an undercut in a direction perpendicular to the inner surface of the crucible wall such that the tablet is mechanically fixed in the crucible wall. The tablet is fixed by a form fit. It is also possible to fix the tablet in the crucible wall by gluing or sintering. In particular, the tablet does not extend into the interior of the crucible. Depending on a concentration of the doping material in the silicon melt and on a distribution of doping material in the silicon melt, more than one doping tablets can be provided in the crucible wall.

According to an advantageous embodiment of the invention, the at least one doping means is provided as a fused-in dopant in the crucible wall. For instance it is possible to mix one or more dopants together with a raw material for building a green body. By sintering, i. e. baking, the green body afterwards, the at least one dopant is fused-in in the crucible wall. In particular, an entire crucible is achieved. The dopant can have a predefined distribution, i. e. concentration profile in the crucible wall.

In an advantageous embodiment of the invention, the doping process is based on a dissolution process, wherein a doping layer is completely dissolved. In particular, the doping is based on a controlled dissolution of the crucible. In particular, it is possible to use the crucible several times, wherein a new doping layer is provided, since a previous doping layer is completely dissolved.

According to an advantageous embodiment of the invention, the doping is based on a dissolution process comprising a dissolution rate in the range of 10 to 50 μm/h.

Further advantages and details of the invention will become apparent from the description of several embodiments by means of the drawing.

### BRIEF DESCRIPTION OF THE DRAWINGS

FIG. 1 shows a schematic cross section through a crucible according to a first embodiment of the invention comprising a complete inner doping layer;

FIG. 2 shows a schematic cross section through a crucible according to a second embodiment of the invention with partial inner doping layer;

FIG. 3 shows a schematic cross section through a crucible according to a third embodiment of the invention comprising a doping tablet; and

FIG. 4 shows a schematic cross section through a crucible according to a fourth embodiment of the invention comprising fused-in dopant in the crucible wall.

### DESCRIPTION OF THE PREFERRED EMBODIMENTS

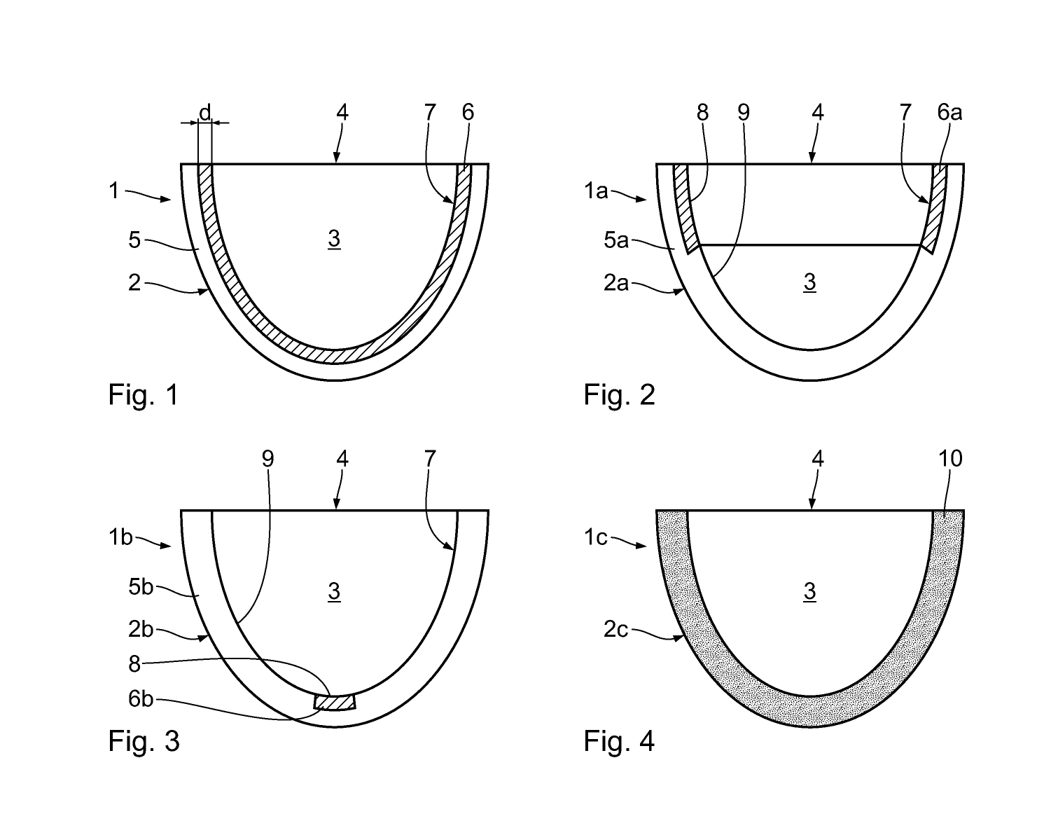

The following is a description of a first embodiment of the invention with a reference to FIG. 1. A crucible 1 for producing a silicon block comprises a crucible wall 2 surrounding an interior 3. The crucible 1 is essentially provided as a half shell. The half shell is at least partially shaped spherically. Of course, any desired shape of the crucible 1 is possible which enables the production of a silicon block. In particular, it is possible to provide a cubic or cuboid crucible 1. The crucible 1 further comprises an opening 4 for filling silicon melt into the interior 3. The crucible wall 2 comprises an outer layer 5. The outer layer 5 comprises silicon dioxide SiO₂. The crucible wall 2 comprises an inner layer 6. The inner layer 6 comprises at least one doping means as a dopant for the silicon melt in the interior 3. In particular, Ga₂O₃, B₂O₃, GeO, BN, Si₃N₄, Si₃(PO₄)₄ and SiAlON can be used as material for the at least one doping means. The at least one doping means is in particular of a material, which dissolves into a melt in the crucible 1. It is in particular of a material, which dissolves into a silicon melt. In other words, the material has a melt temperature lower than that of silicon. The dopant can also be released into the silicon melt in gaseous form when the doping means is in contact with the silicon melt.

The inner layer 6 is also named as doping layer, since the at least one doping means is provided in the doping layer. The doping layer fully provides an inner surface 7 of the crucible wall 2.

That means that the crucible wall 2 comprises at least one doping means for providing a dopant for doping a silicon melt within the crucible 1.

The doping means can be provided in form of grains. The grain size of the at least one doping means is smaller than 50 μm. Thus, the at least one doping material has a grain size being small enough to dissolve quickly into the molten silicon in order to avoid particle bombardment at the liquid/solid silicon interface. The grain size is further large enough in order to avoid release thereof into the silicon melt.

The at least one doping means is at least one of crystalline and amorphous.

The concentration of the at least one doping means in the crucible wall 2 is in a range of 1 to 500 ppm.

The concentration may vary along a direction parallel to the inner surface 7 of the crucible wall 2 and/or along a direction perpendicular to the inner surface 7 of the crucible wall 2.

The doping layer 6 comprises a thickness d, which is constant along the inner surface 7. Depending on the doping process, the thickness d of the doping layer 6 may vary along the inner surface 7.

The following is a description of a method according to the invention for producing a silicon block. In a first step the crucible 1 is provided, whereas the outer layer 5, preferably made from silicon dioxide, is coated with the doping layer 6. A method for producing a multilayered crucible is known from EP 1 290 250 B1. It is also possible to obtain the at least one doping means as a powder during the production of the crucible itself. Such production method of the crucible is disclosed in EP 1 364 912 B1.

After that silicon is filled into the interior 3 of the crucible 1 through the opening 4. Silicon can be filled into the crucible 1 as a silicon melt. It can also be provided as solid silicon, which is melted in the crucible 1. Then the crystallization of a silicon crystal starts. The crystallization may be carried out with the Czochralski-method or a heat exchange method, in particular a vertical gradient freeze or a Bridgman-method. The silicon crystal is doped with the at least one doping means provided in the doping layer 6 of the crucible wall 2. When using the crucible 1 the doping process is based on a dissolution process of the doping layer 6. The doping is provided by a controlled dissolution of the doping layer 6. Thus, the doping material is directly provided in the silicon melt. Thus, the dopant concentration in the silicon melt is constantly replenished. Depending on the concentration of the at least one doping means in the crucible wall the dopant concentration in the silicon melt is modified. In particular, it is possible to choose the concentration of the at least one doping means in the crucible wall 2 such that the dopant concentration in the silicon melt is constant over the whole crystallization process. Preferably, a dissolution rate of the doping layer 6 is in a range of 10 to 15 μm/h. The doping process is stopped after complete dissolution of the doping layer 6.

After crystallization the silicon crystal is removed from the crucible 1.

The following is a description, with reference to FIG. 2, of an other embodiment of the invention. Identical parts are denoted by the same reference numeral is in the first embodiment to the description of which reference is made. Differently signed parts having the same function are denoted by the same reference numerals with an a added to them.

The difference of the crucible 1a of the second embodiment concerning the first embodiment is that the doping layer 6a provides partially the inner surface 7 of the crucible wall 2a. In other words, the doping layer 6a is applied only to certain regions of the inner surface 7 of the crucible wall 2a. It can be applied to one or more continuous regions of the inner surface 7 of the crucible wall 2a. The regions can cover 10% to 90%, in particular 20% to 80%, in particular 30% to 70% of the inner surface 7 of the crucible wall 2a. That means that adding doping material into the silicon melt is locally restricted. Thus, it is possible to control local differences while adding doping material. According to the illustrated embodiment, the doping layer 6a is provided next to the opening 4 of the crucible 1a. Of course it is possible to provide more than one doping layers 6a. The inner surface 7 comprises a doping surface 8, where the doping layer 6a faces the interior 3. Further, the inner surface 7 comprises a non-doping surface 9 in a region, where the non-doped outer layer 5 faces the interior 3.

The method for producing a silicon block using the crucible 1a is similar to the method using the crucible 1 according to the first embodiment of the invention. The difference is that the at least one doping means is only provided via for the silicon melt via the doping surface 8. In particular, none of the doping means are provided for the silicon melt via the none-doping surface 9. Thus, a controlled and directed doping of the silicon melt is permitted.

The following is a description with reference to FIG. 3, of an other embodiment of the invention. Identical parts are denoted by the same reference numerals as in the first and second embodiments to the description of which reference is made. Differently designed parts having the same function are denoted by the same reference numerals with a b added to them.

The difference of the crucible 1b according to the third embodiment concerning the second embodiment is that the at least one doping means is provided as a doping tablet 6b in the crucible wall 2b. The doping tablet 6b can be a part of the crucible wall 2b. In particular, it is not necessary to provide a doping layer on extended regions of the crucible wall 2b. For instance, it is possible to insert the tablet 6b in a corresponding recess of the crucible wall 2b. In particular, it is possible to provide more than one tablet 6b, whereas a predefined pattern of doping surfaces 8 on the inner surface 7 can be achieved. It is also possible to provide the at least one tablet 6b directly on the inner surface 7 of the crucible wall 2b such that the tablet 6b protrudes into the interior 3.

It is also possible to combine at least two of one or more layers 6 of the first embodiment and one or more partial layers 6a of the second embodiment and one ore more tablets 6b of the third embodiment to provide a crucible with an intended doping surface.

By influencing of the size of the doping surface 8 by varying the size and/or the numbers of the inner layer 6a and/or the tablet 6b the amount of doping can be influenced.

The following is a description, with reference to FIG. 4, of an other embodiment of the invention. Identical parts are denoted by the same reference numerals as in the first to third embodiments of the description of which reference is made. Differently designed parts having the same function are denoted by the same reference numerals with a c added to them.

The main difference between the crucible 1c according to the fourth embodiment and one of the above-mentioned embodiments is that the at least one doping means is provided as a doping powder, e. g. Si₃N₄ and/or BN that is mixed with high-purity silicon dioxide to form a green body. The green body together with the doping powder is baked to the crucible. Thus, the at least one doping material is a fused-in dopant 10 in the crucible wall 2c. The crucible 1c according to the fourth embodiment is an entire crucible.

According to an embodiment at least two, in particular at least three or more different doping means can be provided. They can be provided according to the same or different of the embodiments described above.

It is in particular possible to provide different doping means in different regions of the inner surface of the crucible. By that, different dopants can be released into the silicon melt during different phases of the crystallization process. It is further possible to provide a doping means, which provides two or more different dopants to the silicon melt.

The following is a description of a method for producing a silicon block used the crucible 1c according to the fourth embodiment of the invention. The doping is based on a diffusion process, whereas the at least one doping means diffuses from the crucible wall 2c into the silicon melt in the interior 3. The concentration of the at least one doping means in the crucible wall 2c may be varied in dependence of an intended concentration of the dopant in the silicon melt.

What is claimed is:

1. A crucible for producing a silicon block, the crucible comprising
a. a crucible wall surrounding an interior;
b. an opening for filling silicon into the interior;
wherein the crucible wall comprises at least one doping means for providing dopant to the silicon melt.

2. A crucible according to claim 1, wherein the at least one doping means is provided in the crucible wall with a pre-defined profile leading to pre-defined doping characteristics of said silicon block.

3. A crucible according to claim 1, wherein the at least one doping means is at least one of an oxide, a nitride, a phosphate and a doped silicon powder.

4. A crucible according to claim 3, wherein the at least one doping means is at least one of Ga₂O₃, B₂O₃, GeO, BN, Si₃N₄, Si₃(PO₄)₄ and SiAlON.

5. A crucible according to claim 1, wherein a grain size of the at least one doping means is smaller than 50 μm.

6. A crucible according to claim 1, wherein the at least one doping means is at least one of crystalline and amorphous.

7. A crucible according to claim 1, wherein a concentration of the at least one doping means in the crucible wall is in the range of 1 to 500 ppm.

8. A crucible according to claim 7, wherein the concentration of the at least one doping means is variable along a direction parallel to an inner surface of the crucible wall.

9. A crucible according to claim 7, wherein the concentration of the at least one doping means is variable along a direction perpendicular to an inner surface of the crucible wall.

10. A crucible according to claim 1, wherein the at least one doping means is provided as a doping layer of the crucible wall, said doping layer providing at least partially an inner surface of the crucible wall.

11. A crucible according to claim 10, wherein the doping layer fully providing the inner surface of the crucible wall.

12. A crucible according to claim 10, wherein a thickness of the doping layer is variable.

13. A crucible according to claim 1, wherein the at least one doping means is provided as at least one doping tablet.

14. A crucible according to claim 1, wherein the at least one doping means is provided as a fused-in dopant in the crucible wall.

15. A method for producing a silicon block, the method comprising the following method steps:
providing a crucible according to claim 1;
providing a silicon melt in the interior of the crucible;
starting crystallization of a silicon crystal;
doping the silicon crystal with the at least one doping means;
wherein the doping is based on at least one of a diffusion process and a dissolution process of the at least one doping means.

16. A method according to claim 15, wherein doping is based on a dissolution process, wherein a doping layer is completely dissolved.

17. A method according to claim 15, wherein doping is based on a dissolution process comprising a dissolution rate in the range of 3 to 10 μm/h.
